(19) United States
(12) Patent Application Publication
(10) Pub. No.: US 2016/0314988 A1
(43) Pub. Date: Oct. 27, 2016

(54) SUBSTRATE HEAT TREATMENT APPARATUS AND METHOD

(71) Applicants: SAMSUNG DISPLAY CO., LTD, Yongin-si (KR); TERASEMICON CORPORATION, Hwaseong-si (KR)

(72) Inventors: Sung Guk An, Suwon-si (KR); Jun Heo, Suwon-si (KR); Jong Hyun Yun, Gwangmyeong-si (KR); Kyoung Wan Park, Seongnam-si (KR); Ho Young Kang, Hwaseong-si (KR); Byung Il Lee, Seongnam-si (KR)

(21) Appl. No.: 15/203,524

(22) Filed: Jul. 6, 2016

Related U.S. Application Data
(62) Division of application No. 13/945,324, filed on Jul. 18, 2013.

(30) Foreign Application Priority Data
Feb. 26, 2013 (KR) 10-2013-0020615

(51) Int. Cl. H01L 21/324; F27B 17/00; H01L 21/67

(52) U.S. Cl. CPC H01L 21/324; H01L 21/67109; F27B 17/0025

(57) ABSTRACT

Substrate heat treatment apparatus and method are provided. According to an embodiment of the present invention, there is provided a substrate heat treatment apparatus including an inner shell configured to form a substrate housing space to house at least one substrate, an outer shell configured to cover the inner shell, and having at least one gas hole, and at least one heater configured to heat the substrate, wherein the at least one gas hole is configured to allow a first gas to be injected into a space between the inner shell and the outer shell.

### CROSS-REFERENCE TO RELATED APPLICATIONS

This application is a divisional of U.S. patent application Ser. No. 13/945,324, filed Jul. 18, 2013, which claims priority to and the benefit of Korean Patent Application No. 10-2013-0020615, filed on Feb. 26, 2013, in the Korean Intellectual Property Office, the entire content of both of which is incorporated herein by reference.

### BACKGROUND

1. Field

The following description relates to a substrate heat treatment apparatus and method.

2. Description of the Related Art

To manufacture a display device, semiconductor, or solar cell, a substrate heat treatment apparatus is generally used to heat-treat a substrate. Substrate heat treatment apparatuses are divided into single-substrate type apparatuses, which heat-treat one substrate, and batch type apparatuses, which heat-treat multiple substrates. The single-substrate type substrate heat treatment apparatuses are simple in configuration but are low in productivity. Therefore, the batch type substrate heat treatment apparatuses are mainly used in mass production.

A batch type substrate treatment apparatus generally includes an inner wall (or inner shell) and an outer wall (or outer shell). The inner wall may form a space in which multiple substrates are housed, and the outer wall may surround the inner wall. Here, a space is formed between the inner wall and the outer wall. A gas generated or introduced during the heat treatment of the substrates may condense in the space between the inner wall and the outer wall, thus contaminating the substrate heat treatment apparatus.

To prevent gas condensation in the space between the inner wall and the outer wall, a heater may be installed at the outer wall. This method may be useful for preventing gas condensation but may not be applicable to a large volume of heat treatment apparatus and may reduce the temperature uniformity of the substrates.

### SUMMARY

Aspects of embodiments of the present invention are directed toward a substrate heat treatment apparatus which can prevent gas condensation in a space between an inner wall and an outer wall by adjusting the pressure in the space between the inner wall and the outer wall and the pressure in a substrate housing space.

Aspects of embodiments of the present invention are also directed toward a substrate heat treatment method which can prevent gas condensation in a space between an inner wall and an outer wall by adjusting the pressure in the space between the inner wall and the outer wall and the pressure in a substrate housing space.

However, aspects of embodiments of the present invention are not restricted to the one set forth herein. The above and other aspects of embodiments of the present invention will become more apparent to one of ordinary skill in the art to which the present invention pertains by referencing the detailed description of the present invention given below.

According to an embodiment of the present invention, there is provided a substrate heat treatment apparatus including: an inner shell configured to form a substrate housing space to house at least one substrate; an outer shell configured to cover the inner shell, and having at least one gas hole; and at least one heater configured to heat the substrate, wherein the at least one gas hole is configured to allow a first gas to be injected into a space between the inner shell and the outer shell.

The inner shell may include a heat insulator.

The first gas may include at least one of air, nitrogen gas, helium gas, hydrogen gas, and oxygen gas.

The apparatus may further include at least one gas pipe configured to form a passage through which the first gas flows, wherein the at least one gas hole may include a plurality of gas holes coupled together by the gas pipe.

The at least one heater may include a plurality of heaters, and may penetrate the inner shell and the outer shell and support the substrate.

A pressure in the space between the inner shell and the outer shell may be higher than a pressure in the substrate housing space.

The apparatus may further include: a first inner pressure sensor located in the space between the inner shell and the outer shell; a second inner pressure sensor located in the substrate housing space; and a pressure controller configured to compare a first pressure measured by the first inner pressure sensor with a second pressure measured by the second inner pressure sensor and to adjust the first pressure to be higher than the second pressure based on the comparison.

The apparatus may further include at least one first gas supplier configured to supply the first gas, wherein the pressure controller may be configured to control a difference between the first pressure and the second pressure to be equal to or greater than a reference value by adjusting an amount of the first gas supplied from the at least one first gas supplier per unit of time.

The apparatus may further include: a first gas supplier configured to supply the first gas, wherein the first gas supplier includes a first gas chamber configured to store the first gas, the first gas chamber including a plurality of sub-chambers, each sub-chamber configured to store an associated one of a plurality of types of first gases and a plurality of sub-chamber valves, each sub-chamber valve installed in an associated one of the plurality of sub-chambers.

The apparatus may further include: a second gas supplier configured to supply a second gas to the substrate housing space; and a valve controller configured to select a first gas corresponding to the second gas and to selectively open or close the plurality of sub-chamber valves based on the selected first gas.

The valve controller may be configured to open one sub-chamber valve of the plurality of sub-chamber valves associated with the first gas corresponding to the second gas, and to close other sub-chamber valves of the plurality of sub-chamber valves.

According to an embodiment of the present invention, there is provided a substrate heat treatment apparatus including: an inner shell configured to form a substrate housing space to house at least one substrate; an outer shell configured to cover the inner shell, and including at least one gas hole; and at least one heater configured to heats the substrate, wherein the at least one gas hole is configured to allow a gas inside the outer shell to be discharged to the outside of the outer shell.

The apparatus may further include at least one gas pipe to form a passage through which the gas is discharged, wherein the at least one gas hole may include a plurality of gas holes coupled together by the gas pipe.

A pressure in a space between the inner shell and the outer shell may be lower than a pressure in the substrate housing space.

The apparatus may further include: a first inner pressure sensor located in the space between the inner shell and the outer shell; a second inner pressure sensor located in the substrate housing space; and a pressure controller configured to compare a first pressure measured by the first inner pressure sensor with a second pressure measured by the second inner pressure sensor and to adjust the first pressure to be lower than the second pressure based on the comparison.

The apparatus may further include a vacuum pump coupled to the at least one gas hole, wherein the pressure controller is configured to control a difference between the first pressure and the second pressure to be equal to or greater than a reference value by adjusting a driving force of the vacuum pump.

The apparatus may further include a reaction gas supplier configured to supply a reaction gas to the substrate housing space, wherein the at least one gas hole is configured to discharge the reaction gas and a gas generated from the substrate.

According to an embodiment of the present invention, there is provided a substrate heat treatment method including: feeding one or more substrates into a space surrounded by an inner shell and heating the substrates; and injecting a first gas into a space between the inner shell and an outer shell configured to surround the inner shell, or discharging a gas inside the outer shell to the outside of the outer shell.

The injecting of the first gas may include adjusting a pressure in the space between the inner shell and the outer shell to be higher than a pressure in the space surrounded by the inner shell.

The discharging of the gas inside the outer shell to the outside of the outer shell may include adjusting a pressure in the space between the inner shell and the outer shell to be lower than a pressure in the space surrounded by the inner shell.

### BRIEF DESCRIPTION OF THE DRAWINGS

The above and other aspects and features of the present invention will become more apparent by describing in detail example embodiments thereof with reference to the attached drawings, in which:

FIG. 1 is an exploded perspective view of a substrate heat treatment apparatus, according to an example embodiment of the present invention;

FIG. 2 is an exploded perspective view of the substrate heat treatment apparatus shown in FIG. 1, excluding gas pipes and heaters, according to an example embodiment of the present invention;

FIG. 3 is a cross-sectional view taken along line III-III′ of FIG. 1, according to an example embodiment of the present invention;

FIG. 4 is a plan view of the substrate heat treatment apparatus shown in FIG. 1, according to an example embodiment of the present invention;

FIG. 5 is an enlarged plan view of a first gas supplier included in the substrate heat treatment apparatus shown in FIG. 1, according to an example embodiment of the present invention;

FIG. 6 is an enlarged cross-sectional view of a portion VI of FIG. 3, according to an example embodiment of the present invention;

FIG. 7 is a block diagram of a pressure controller included in the substrate heat treatment apparatus shown in FIG. 1, according to an example embodiment of the present invention;

FIG. 8 is a block diagram of a valve controller included in the substrate heat treatment apparatus shown in FIG. 1, according to an example embodiment of the present invention;

FIG. 9 is an exploded perspective view of a substrate heat treatment apparatus, according to another example embodiment of the present invention;

FIG. 10 is a plan view of the substrate heat treatment apparatus shown in FIG. 9, according to an example embodiment of the present invention;

FIG. 11 is an exploded perspective view of a substrate heat treatment apparatus, according to another example embodiment of the present invention;

FIG. 12 is a plan view of the substrate heat treatment apparatus shown in FIG. 11, according to an example embodiment of the present invention;

FIG. 13 is a plan view of a substrate heat treatment apparatus, according to another example embodiment of the present invention;

FIG. 14 is an enlarged cross-sectional view of a portion corresponding to the portion VI of the substrate heat treatment apparatus of the embodiment shown in FIG. 13, according to an example embodiment of the present invention; and

FIG. 15 is a block diagram of a pressure controller included in the substrate heat treatment apparatus of the embodiment shown in FIG. 13, according to an example embodiment of the present invention.

### DETAILED DESCRIPTION

Aspects and features of the present invention and methods of accomplishing the same may be understood more readily by reference to the following detailed description of example embodiments and the accompanying drawings. The present invention may, however, be embodied in many different forms and should not be construed as being limited to the embodiments set forth herein. Rather, these embodiments are provided so that this disclosure will thoroughly convey the concept of the invention to those skilled in the art. However, the scope of the present invention will only be defined by the appended claims. Thus, in some embodiments, well-known structures and devices are not shown so as not to obscure the description of the invention with unnecessary detail. Like numbers refer to like elements throughout. In the drawings, the thickness of layers and regions may be exaggerated for clarity.

It will be understood that when an element or layer is referred to as being “on,” or “connected to” another element or layer, it can be directly on or connected to the other element or layer or intervening element(s) or layer(s) may be present. In contrast, when an element is referred to as being “directly on” or “directly connected to” another element or layer, there are no intervening elements or layers present. As used herein, the term “and/or” includes any and all combinations of one or more of the associated list of items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Embodiments described herein will be described while referring to plan views and/or cross-sectional views by way of schematic diagrams of the invention. Accordingly, the example views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and do not limit aspects of the invention.

As used herein, a “substrate” may be, but is not limited to, a semiconductor substrate, a display substrate, a thin-film transistor (TFT) substrate, a printed circuit board (PCB), or a flexible substrate. In addition, the term “substrate” may not only refer to a thick “substrate,” as the term suggests, but also refer to a “film” or a “thin layer.”

Furthermore, a “substrate heat treatment apparatus,” as used herein, may refer to not only an apparatus for simply heating a substrate but also an apparatus for processing a substrate using heat. For example, the “substrate heat treatment apparatus” may be, but is not limited to, an aging apparatus, a chemical vapor deposition (CVD) apparatus that performs chemical treatment as well as heat treatment, or a physical vapor deposition (PVD) apparatus that performs physical treatment as well as heat treatment.

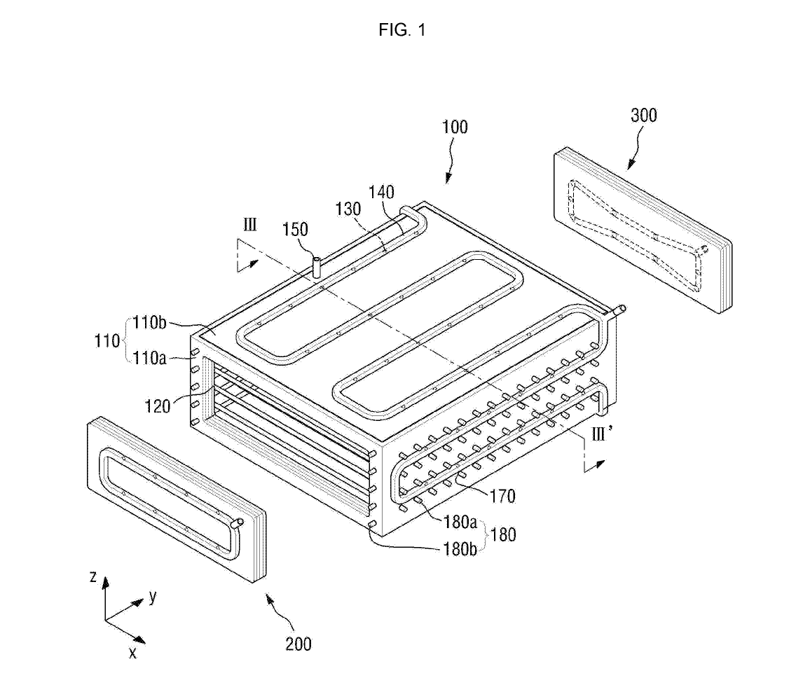

Hereinafter, embodiments of the present invention will be described with reference to the attached drawings. FIGS. 1 through 8 may pertain to the same or different embodiments.

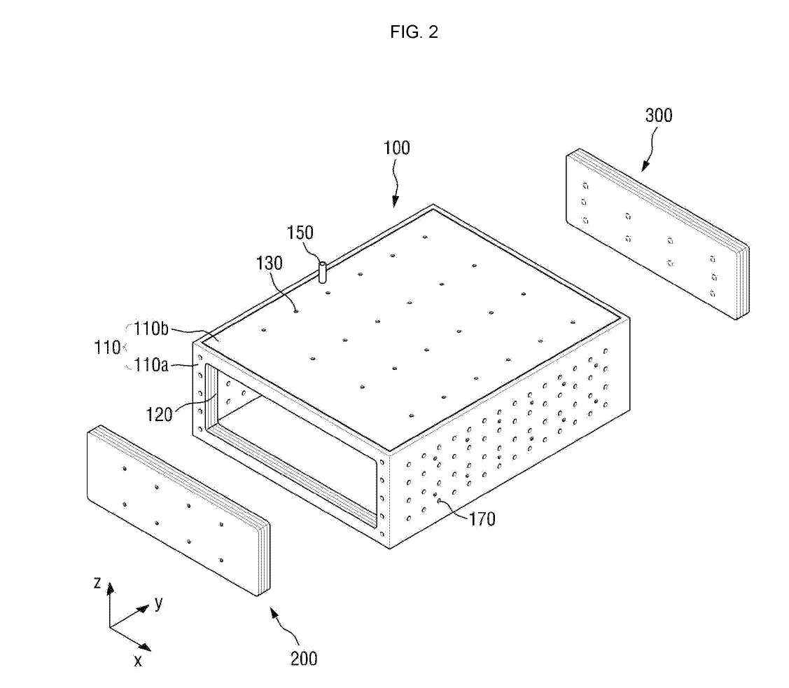

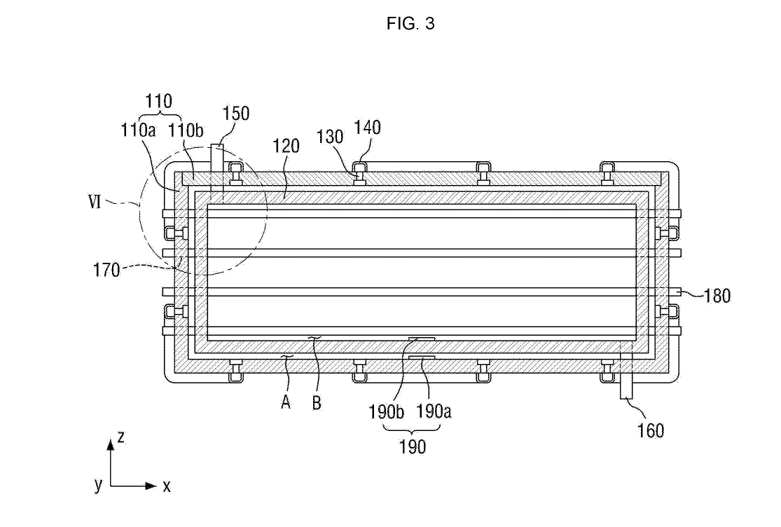

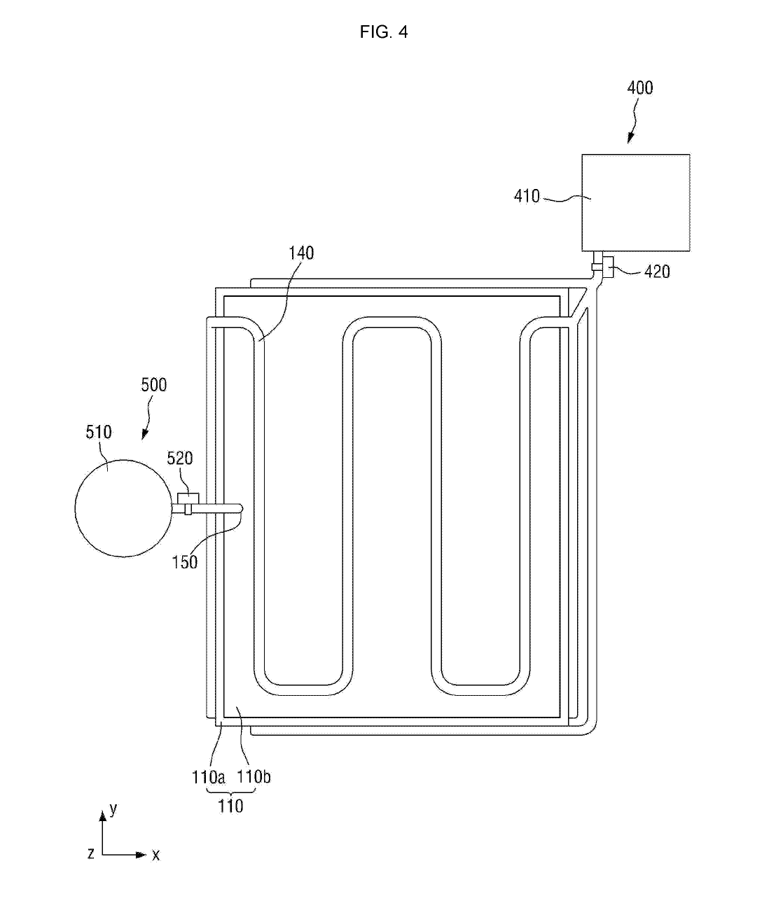

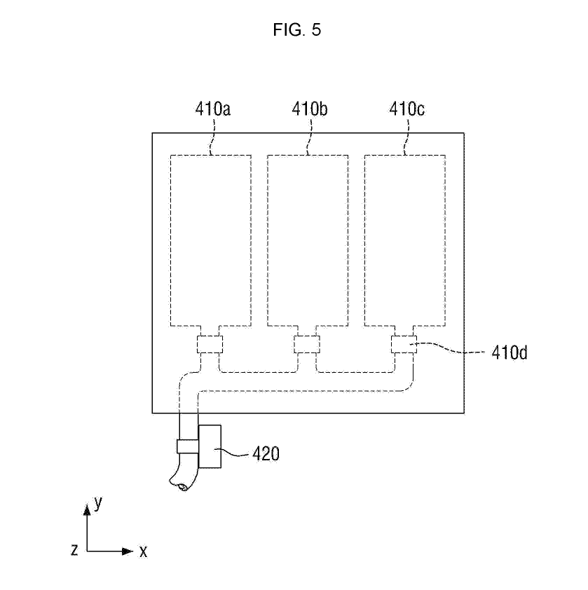

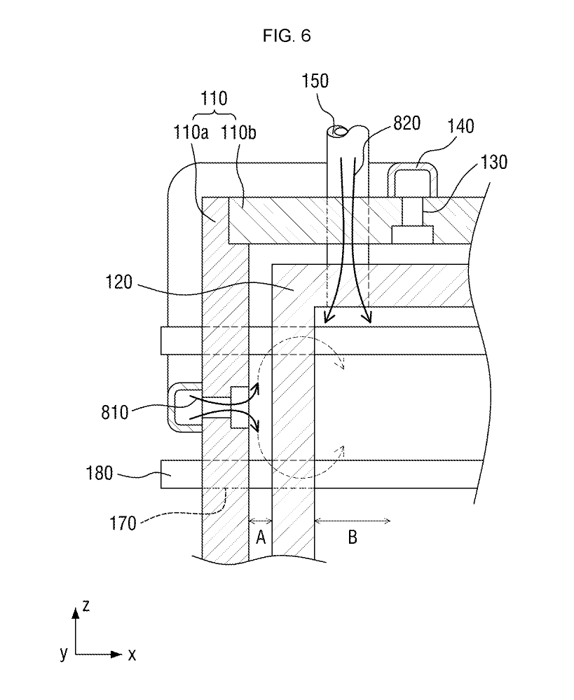

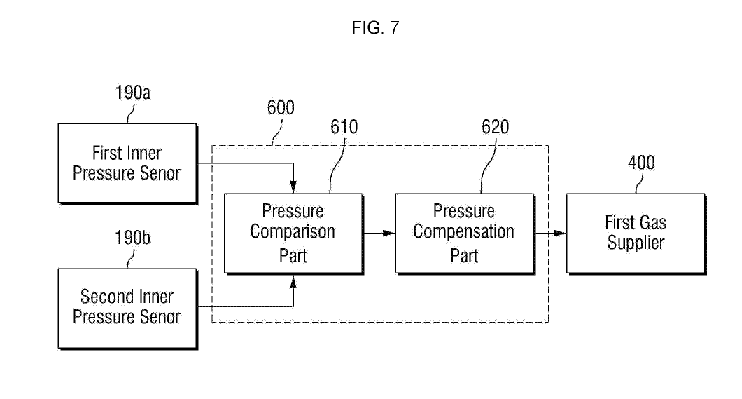

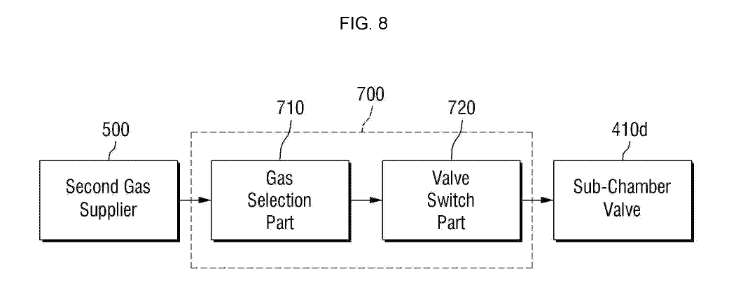

FIG. 1 is an exploded perspective view of a substrate heat treatment apparatus, according to an embodiment of the present invention. FIG. 2 is an exploded perspective view of the substrate heat treatment apparatus of the embodiment shown in FIG. 1, excluding gas pipes 140 and heaters 180, according to an example embodiment of the present invention. FIG. 3 is a cross-sectional view taken along line III-III′ of FIG. 1. FIG. 4 is a plan view of the substrate heat treatment apparatus shown in FIG. 1. FIG. 5 is an enlarged plan view of a first gas supplier 400 included in the substrate heat treatment apparatus of the embodiment shown in FIG. 1. FIG. 6 is an enlarged cross-sectional view of a portion VI of FIG. 3. FIG. 7 is a block diagram of a pressure controller 600 included in the substrate heat treatment apparatus of the embodiment shown in FIG. 1. FIG. 8 is a block diagram of a valve controller 700 included in the substrate heat treatment apparatus of the embodiment shown in FIG. 1.

Referring to FIGS. 1 through 8, the substrate heat treatment apparatus, according to the current embodiment, may include a body 100, a front door 200, a back door 300, the first gas supplier 400, a second gas supplier 500, the pressure controller 600, and the valve controller 700.

The body 100 may include an inner wall 120, an outer wall 110, and at least one heater 180. Further, the body 100 may include a gas pipe 140, a second gas supply pipe 150, a discharge pipe 160, and an inner pressure sensor 190.

The inner wall 120 may be formed of a heat insulator. The heat insulator may be a material that covers the outside of a place which should be maintained at a constant temperature to reduce the transfer of heat to the outside of the place or the introduction of heat to the inside of the place. The heat insulator may be not only a material used in a temperature range of approximately 500° C. to 1,100° C. but also a cold insulator used at a temperature of approximately 100° C. or below, a heat insulating material with a temperature range of 100° C. to 500° C., or an insulating refractory material usable at a temperature of 1100° C. or above. The inner wall 120 may be formed of a material with a low thermal conductivity. In addition, the inner wall 120 may be formed of a porous material. The inner wall 120 may also have a multilayer structure. The inner wall 120 may be formed of an organic material, an inorganic material, or a combination of an organic material and an inorganic material. In an example embodiment, the inner wall 120 may be formed of cork, asbestos, glass wool, quartz wool, magnesium carbonate, magnesia, calcium silicate, neo-ceramic, or a combination of these materials. Also, one side or both sides of the inner wall 120 may be coated with an anti-corrosion material such as a fluorine-containing compound.

The inner wall (or inner shell) 120 may form a substrate housing space in which at least one substrate is housed. In an example embodiment, one inner wall 120 may be bent to form a cubic space, and at least one substrate may be housed in the cubic space. In another example embodiment, a plurality of inner walls 120 may be bonded together to form a completely closed space or a partially closed (i.e., partially open) space. In this case, the inner walls 120 may be designed to be separable from each other, so that components inside the inner walls 120 can be repaired and replaced without undue effort. In the example embodiment of FIG. 1, one inner wall 120 is bent to form a partially closed space. However, the present invention is not limited thereto.

The outer wall (or outer shell) 110 may cover the inner wall 120. The outer wall 110 covering the inner wall 120 may protect the inner wall 120 and at least one substrate housed in the inner wall 120. The shape of a space formed inside the outer wall 110 may be similar to that of the space formed inside the inner wall 120. However, the volume of the space formed inside the outer wall 110 may be greater than that of the space formed inside the inner wall 120. The outer wall 110 may be formed of a monometallic material or an alloy. In an example embodiment, the outer wall 110 may be formed of steel use stainless (SUS). In addition, the outer wall 110 may be coated with an anti-corrosion material such as a fluorine-containing compound.

The outer wall 110 may include a base 110a and a cover 110b. The base 110a may cover all portions of the substrate heat treatment apparatus, excluding a top surface of the substrate heat treatment apparatus and two entrances. The cover 110b may be formed on the top surface of the substrate heat treatment apparatus and may be separable from the base 110a. Because the cover 110b is separable from the base 110a, components installed inside the substrate heat treatment apparatus can be easily repaired and replaced.

A space may be formed between the outer wall 110 and the inner wall 120. The space formed between the outer wall 110 and the inner wall 120 may be an intentionally designed space to accommodate other structures. Alternatively, the space between the outer wall 110 and the inner wall 120 may be an unintended result of weak adhesion between the outer wall 110 and the inner wall 120 in the process of manufacturing the substrate heat treatment apparatus. In FIG. 3, the space between the outer wall 110 and the inner wall 120 is illustrated as a first space A, and the substrate housing space in which at least one substrate is housed is illustrated as a second space B.

Each of the outer wall 110 and the inner wall 120 may include at least one heater hole 170. The heater hole 170 may be a hole through which the heater 180 passes. In an example embodiment, the heater hole 170 of the outer wall 110 may overlap (or be aligned with) the heater hole 170 of the inner wall 120. In addition, the heater hole of the outer wall 110 may have the same shape and size as the heater hole 170 of the inner wall 120. As described above, because a space can be formed between the outer wall 110 and the inner wall 120, the heater hole 170 of the outer wall 110 may be separated from the heater hole 170 of the inner wall 120 by a distance (e.g., a set or predetermined distance).

In an embodiment, more than one heater hole 170 may be formed. The heater holes 170 may be formed in a first side (or first side surface) of the body 100 and a second side or (second side surface) which is opposite the first side. The heater holes 170 may also be formed in another side (or another side surface) adjacent to each of the first and second side of the body 100. In the example embodiment of FIGS. 1 through 3, 56 heater holes 170 may be formed in a first side of the body 100, 56 heater holes 170 may be formed in a second side which is opposite the first side of the body 100, ten heater holes 170 may be formed in another side adjacent to the first side of the body 100, and ten heater holes 170 may be formed in another side adjacent to the second side of the body 100. However, the present invention is not limited thereto. In addition, the heater holes 170 formed in the first side of the body 100 may exhibit symmetry with the heater holes 170 formed in the second side of the body 100.

The heater holes 170 formed in any one side of the body 100 may be separated from each other. The heater holes 170 may be separated from each other by equal distances. However, the present invention is not limited thereto, and the heater holes 170 may also be separated from each other by different distances. The heater holes 170 may be arranged in various suitable patterns. The heater holes 170 may be arranged in a matrix pattern as shown in FIGS. 1 and 2. However, the present invention is not limited thereto, and the heater holes 170 may also be arranged in a row.

The outer wall (or outer shell) 110 may include at least one gas hole 130. As illustrated in FIG. 6, the gas hole 130 may be a passage through which a first gas 810 flows. The first gas 810 may be introduced into the space between the inner wall (or inner shell) 120 and the outer wall 110 through the gas hole 130. The first gas 810 may include at least one of, but not be limited to, air, nitrogen gas, helium gas, hydrogen gas, and oxygen gas. In an example embodiment, the first gas 810 may be a gas that hardly chemically reacts with another material, for example, an inert gas such as neon gas, argon gas, etc. In another example embodiment, the first gas 810 may be a gas that reacts with a substrate inside the body 100 or a structure formed on the substrate.

The gas hole 130 may become larger in size (e.g., larger in diameter) toward the inside of the substrate heat treatment apparatus. Referring to FIGS. 3 and 6, an inner portion of the gas hole 130 may be larger in size (e.g., larger in diameter) than an outer portion of the gas hole 130. In FIGS. 3 and 6, the gas hole 130 having a step difference is illustrated. However, the present invention is not limited thereto, and the gas hole 130 can be formed in various suitable shapes.

In an embodiment, more than one gas hole 130 may be formed. The gas holes 130 may be formed in at least one side of the body 100. In an example embodiment, the gas holes 130 may be formed in all sides of the body 100. The gas holes 130 formed in a side of the body 100 may be separated from each other, by, for example, equal distances. However, the present invention is not limited thereto, and the gas holes 130 may also be separated from each other by different distances. In an example, 24 gas holes 130 may be formed in each of top and bottom sides of the body 100, and 12 gas holes 130 may be formed in each of a side (e.g., a left side) of the body 100 and an opposite side (e.g., a right side) of the body 100. However, the present invention is not limited thereto. In addition, the gas holes 130 may be arranged in various suitable patterns. The gas holes 130 may be arranged in a matrix pattern as shown in FIGS. 1 and 2. However, the present invention is not limited thereto, and the gas holes 130 may also be arranged in a row.

The gas hole 130 may be formed only in (or through) the outer wall 110. For example, the gas hole 130 may not be formed in (or through) the inner wall 120. In one embodiment, both the heater hole 170 and the gas hole 130 may be formed in (or through) the outer wall 110. However, only the heater hole 170 may be formed in (or through) the inner wall 120.

The outer wall 110 and the inner wall 120 may form at least one entrance through which a substrate is fed into or removed from the substrate housing space. In an embodiment, more than one entrance may be formed and may be located in a front side of the body 100 and the back side which is opposite the front side of the body 100. In the example embodiment of FIGS. 1 and 2, the outer wall 110 and the inner wall 120 form two entrances. In this case, a substrate may be fed through the entrance formed at the front of the body 100 and removed through the entrance formed at the back of the body 100. To prevent the introduction of a foreign substance into the substrate housing space when a substrate is fed into and removed from the substrate housing space through the entrances, an air curtain may be installed at each of the entrances.

The heater 180 may be disposed within the substrate housing space. The heater 180 may heat at least one substrate. The heater 180 may be shaped like a rod which extends in a direction. However, the shape of the heater 180 is not limited to the rod shape, and the heater 180 may also be plate-shaped. The heater 180 may heat a substrate in direct contact with the substrate. Alternatively, the heater 180 may heat a substrate in indirect contact with the substrate, that is, with another structure interposed between the heater 180 and the substrate. The heater 180 may heat as well as support a substrate.

The heater 180 may penetrate the inner wall (or inner shell) 120 and the outer wall (or outer shell) 110. For example, the heater 180 may be inserted into the heater hole 170. In an example embodiment, the heater 180 may penetrate the inner wall 120 and the outer wall 110 at a side (e.g., a left side) of the body 100, pass through the substrate housing space, and then penetrate the inner wall 120 and the outer wall 110 at an opposite side (e.g., a right side) of the body 100.

In an embodiment, more than one heater 180 may be provided. The heaters 180 may be arranged side by side in the substrate housing space. The heaters 180 may be arranged side by side to be parallel to the top side of the body 100, that is, the cover 110b. In addition, the heaters 180 may form a plurality of layers, wherein at least one substrate may be placed on one layer.

The heater 180 may include a main heater 180a and an auxiliary heater 180b. The main heater 180a may be designed to directly heat a substrate, and the auxiliary heater 180b may be designed to prevent the loss of heat existing in the substrate housing space. While the main heater 180a contacts a substrate, the auxiliary heater 180b may not contact the substrate. In addition, the main heater 180a and the auxiliary heater 180b may be configured (or placed) to cross (or intersect) each other. In the example embodiment of FIG. 1, the main heater 180a may extend in an x direction, and the auxiliary heater 180b may extend in a y direction.

Referring to FIG. 6, the gas pipe 140 may form a passage through which the first gas 810 flows. For example, the first gas 810 supplied from the first gas supplier 400 may move to the gas hole 130 through the gas pipe 140 and then flow into the space between the outer wall 110 and the inner wall 120 through the gas hole 130.

The gas pipe 140 may be formed of a flexible material. However, the material that forms the gate pipe 140 is not limited to the flexible material, and the gas pipe 140 may be formed of various suitable materials that inhibit the outflow of the first gas 810. The gas pipe 140 may be integrally formed with the outer wall 110. However, the present invention is not limited thereto, and the gas pipe 140 can be separated from the outer wall 110.

The gas pipe 140 may be placed (or positioned) to cover the gas hole 130. If the gas hole 130 is formed in a plurality, the gas pipe 140 may be placed to cover all of the gas holes 130. For example, the gas holes 130 may be connected to each other by the gas pipe 140. In the example embodiment of FIG. 1, one gas pipe 140 covers all gas holes 130 formed in the outer wall 110. However, the present invention is not limited thereto, and a plurality of gas pipes 140 may also cover other gas holes 130, such as those that may be formed in the front door 200 and the back door 300. In addition, the gas pipe 140 may be configured (or placed) in various suitable patterns. In the example embodiment of FIG. 1, the gas pipe 140 may be configured (or placed) in a wavy pattern.

The second gas supply pipe 150 may penetrate the outer wall (or outer shell) 110 and the inner wall (or inner shell) 120. In an example embodiment, a second gas 820 may be a reaction gas used to heat-treat a substrate. In another example embodiment, the second gas 820 may be, but is not limited to, an inert gas. The second gas 820 may be different from the first gas 810. However, the present invention is not limited thereto, and the second gas 820 may be the same as (or identical to) the first gas 810. The second gas supply pipe 150 may be connected to the second gas supplier 500. For example, the second gas 820 supplied from the second gas supplier 500 may be introduced into the substrate housing space through the second gas supply pipe 150.

Referring to FIG. 3, the discharge pipe 160 may be formed at a location opposite the second gas supply pipe 150. The discharge pipe 160 may be formed at a corner of the body 100 diagonal to another corner of the body 100 at which the second gas supply pipe 150 is formed. Like the second gas supply pipe 150, the discharge pipe 160 may penetrate the outer wall 110 and the inner wall 120. The discharge pipe 160 may discharge a gas existing within the substrate housing space to the outside of the substrate housing space. Additionally, the discharge pipe 160 may control the pressure in the substrate housing space.

The second gas supply pipe 150 can be omitted in a process that does not require a reaction gas, for example, in a process of simply heating a substrate.

The inner pressure sensor 190 may measure the pressure inside the space surrounded by the outer wall 110. For example, the inner pressure sensor 190 may convert the pressure of a gas inside the space surrounded by the outer wall 110 into an electrical signal and provide the electrical signal to the pressure controller 600 which will be described later. In an example embodiment, the inner pressure sensor 190 may be an integrated circuit (IC) pressure sensor, however, it is not limited thereto.

The inner pressure sensor 190 may include a first inner pressure sensor 190a and a second inner pressure sensor 190b. The first inner pressure sensor 190a may be located in the first space A, between the outer wall 110 and the inner wall 120, to measure the pressure in the space between the outer wall 110 and the inner wall 120. The second inner pressure sensor 190b may be located in the substrate housing space to measure the pressure in the substrate housing space. As illustrated in FIG. 3, the first inner pressure sensor 190a and the second inner pressure sensor 190b may overlap each other. However, the present invention is not limited thereto.

The front door 200 and the back door 300 may be installed at two entrances through which a substrate is fed into and removed from the substrate housing space. The front door 200 and the back door 300 may open or close the two entrances. In an example embodiment, the front door 200 may be installed at the entrance formed at the front of the body 100, and the back door 300 may be installed at the entrance formed at the back of the body 100. A substrate may be fed into the body 100 through the front entrance in a state where the front door 200 is open and may be removed from the body 100 through the back entrance in a state where the back door 300 is open. During a substrate heat treatment process, the front door 200 and the back door 300 may be closed to seal the body 100.

Like the body 100, each of the front door 200 and the back door 300 may include an inner wall (or inner shell) 120 and an outer wall (or outer shell) 110. The inner wall 120 and the outer wall 110 of each of the front door 200 and the back door 300 may have the same structures as the inner wall 120 and the outer wall 110 of the body 100. In addition, at least one gas hole 130 may be formed in the outer wall 110 of each of the front door 200 and the back door 300. In the example embodiment of FIGS. 1 and 2, eight gas holes 130 may be formed in the front door 200, and ten gas holes 130 may be formed in the back door 300. The gas holes 130 may be connected to each other by a circular or ribbon-shaped gas pipe 140.

The first gas supplier 400 may store the first gas 810 and supply the first gas 180 to the space between the inner wall 120 and the outer wall 110. In an example embodiment, the first gas supplier 400 may be placed adjacent to a corner of the body 100. However, the present invention is not limited thereto, and the first gas supplier 400 may also be integrally formed with the body 100.

The first gas supplier 400 may include a first gas chamber 410 and a first gas pressure gauge 420. The first gas chamber 410 may provide a space which stores at least one first gas 810. The first gas supplier 400 may be connected to the gas pipes 140 installed on the body 100, the front door 200 and the back door 300 and supply the first gas 810 to each of the gas pipes 140.

The first gas chamber 410 may store a plurality of first gases 810, and the first gases 810 may be stored in a plurality of sub-chambers, respectively. In the example embodiment of FIG. 5, the first gas chamber 410 may include a first sub-chamber 410a, a second sub-chamber 410b, and a third sub-chamber 410c. Each of the first through third sub-chambers 410a through 410c may store different types of first gases 810. All of the first through third sub-chambers 410a through 410c may be connected to the gas pipes 140, and a sub-chamber valve 410d which can open or close a sub-chamber may be installed for each of the first through third sub-chambers 410a through 410c.

The first gas pressure gauge 420 may measure the pressure of the first gas 810 supplied from the first gas supplier 400 and display the measured pressure. A user/worker or computer may identify whether the first gas supplier 400 malfunctions by checking the pressure displayed on the first gas pressure gauge 420.

As shown in FIG. 5, the second gas supplier 500 may store the second gas 820 and supply the second gas 820 to the substrate housing space. In an example embodiment, the second gas supplier 500 may be placed adjacent to a side of the body 100. However, the present invention is not limited thereto, and the second gas supplier 500 may also be integrally formed with the body 100.

The second gas supplier 500 may include a second gas chamber 510 and a second gas pressure gauge 520. The second gas chamber 510 may provide a space which stores at least one second gas 820. The second gas supplier 500 may be connected to the second gas supply pipe 150 installed on the body 100 and supply the second gas 820 to the second gas supply pipe 150. Although not shown in the drawings, the second gas chamber 510 may also include a plurality of sub-chambers, and different types of second gases 820 may be stored in the sub-chambers.

The second gas pressure gauge 520 may measure the pressure of the second gas 820 supplied from the second gas supplier 500 and display the measured pressure. A user/worker or computer may identify whether the second gas supplier 500 malfunctions by checking the pressure displayed on the second gas pressure gauge 520.

The second gas supplier 500 can be omitted in a process that does not require a reaction gas, for example, in a process of simply heating a substrate.

Referring to FIG. 6, the first gas 810 introduced into the space between the inner wall (or inner shell) 120 and the outer wall (or outer shell) 110 may flow not only into the space between the inner wall 120 and the outer wall 110 but also into the substrate housing space. In the example embodiment of FIG. 6, the first gas 810 may be introduced into the substrate housing space through the heater hole 170 formed in the inner wall 120. However, the present invention is not limited thereto. For example, if the inner wall 120 is assembled by combining a plurality of heat insulators, the first gas 810 may pass through a gap between adjacent heat insulators. In addition, if the heat insulators are assembled using screws, the first gas 810 may pass through screw holes. In FIG. 6, because the amount of the first gas 810 introduced into the substrate housing space through the heater hole 170 is less than that of the first gas 810 introduced into the space between the inner wall 120 and the outer wall 110 through the gas hole 130, the first gas 810 introduced into the substrate housing space through the heater hole 170 is indicated by dotted lines.

In an embodiment, the second gas 820 is introduced directly into the substrate housing space through the second gas supply pipe 150.

The pressure in the space between the inner wall 120 and the outer wall 110 is higher than the pressure in the substrate housing space. In an example embodiment, the amount of the first gas 810 introduced into the space between the inner wall 120 and the outer wall 110 per unit of time is greater than that of the second gas 820 introduced into the substrate housing space per unit of time. In another example embodiment, a large amount of gas is discharged through the discharge pipe 160. Therefore, the pressure in the substrate housing space may be lower than the pressure in the space between the inner wall 120 and the outer wall 110.

As shown in FIG. 7, the pressure controller 600 may compare the pressure measured by the first inner pressure sensor 190a and the pressure measured by the second inner pressure sensor 190b and adjust the pressure in the space between the inner wall 120 and the outer wall 110 to be higher than the pressure in the substrate housing space. Although not shown in FIGS. 1 through 6, the pressure controller 600 may be formed at the body 100 or may be separated from the body 100 by a distance (e.g., a set or predetermined distance). Additionally, the pressure controller 600 may include a screen and display its operation on the screen.

The pressure controller 600 may include a pressure comparison part 610 and a pressure compensation part 620.

The pressure comparison part 610 may receive the pressure (hereinafter, referred to as first pressure) in the space between the inner wall 120 and the outer wall 110 and the pressure (hereinafter, referred to as second pressure) in the substrate housing space respectively from the first inner pressure sensor 190a and the second inner pressure sensor 190b in the form of data and calculate a difference value between the first pressure and the second pressure. In an example embodiment, the pressure comparison part 610 calculates the difference value by subtracting the second pressure from the first pressure.

The pressure compensation part 620 may receive the difference value between the first pressure and the second pressure from the pressure comparison part 610 and compensate for the pressure in the space between the inner wall 120 and the outer wall 110 and the pressure in the substrate housing space based on the difference value. In an example embodiment, the pressure compensation part 620 receives the difference value, obtained by subtracting the second pressure from the first pressure, from the pressure comparison part 610 and compares the difference value with a reference value (e.g., a preset value). When the difference value obtained by subtracting the second pressure from the first pressure is greater than the reference value, the pressure compensation part 620 may reduce the amount of the first gas 810 supplied from the first gas supplier 400 per unit of time or may not perform pressure compensation. When the difference value obtained by subtracting the second pressure from the first pressure is less than the reference value, the pressure compensation part 620 may increase the amount of the first gas 810 supplied from the first gas supplier 400 per unit of time. In another example embodiment, when the difference value obtained by subtracting the second pressure from the first pressure is greater than the reference value, the pressure compensation part 620 may reduce the amount of gas discharged through the discharge pipe 160 per unit of time or may not perform any pressure compensation. When the difference value obtained by subtracting the second pressure from the first pressure is less than the reference value, the pressure compensation part 620 may increase the amount of gas discharged through the discharge pipe 160 per unit of time.

As shown in FIG. 8, the valve controller 700 may select a first gas 810 corresponding to the second gas 820 and selectively open or close the sub-chamber valves 410d. Although not shown in FIGS. 1 through 6, the valve controller 700 may be formed at the body 100 or may be separated from the body 100 by a distance (e.g., a set or predetermined distance). Additionally, the valve controller 700 may include a screen and display its operation on the screen.

The valve controller 700 may include a gas selection part 710 and a valve switch part 720.

The gas selection part 710 may receive information about the second gas 820 from the second gas supplier 500 in the form of data. The gas selection part 710 may select a first gas 810 corresponding to the received information about the second gas 820. The first gas 810 corresponding to the received information about the second gas 820 may be a gas that does not react with the second gas 820. However, the present invention is not limited thereto, and the first gas 810 may also be the same as (or identical to) the second gas 820. The gas selection part 710 may provide information about the selected first gas 810 to the valve switch part 720 in the form of data.

The valve switch part 720 may selectively open or close the sub-chamber valves 410 based on the information about the selected first gas 810 received from the gas selection part 710. In an example embodiment, the valve switch part 720 opens the sub-chamber valve 410 installed in a sub-chamber, which stores a first gas 810 corresponding to the information about the selected first gas 810 from the gas selection part 710, and closes the sub-chamber valves 410d installed in the other sub-chambers.

As described above, in the substrate heat treatment apparatus, according to the current embodiment, the pressure in the space between the inner wall (or inner shell) 120 and the outer wall (or outer shell) 110 is higher than the pressure in the substrate housing space. Therefore, a gas existing in the substrate housing space may not flow into the space between the inner wall 120 and the outer wall 110. For example, it is possible to prevent generation of a foreign substance, which condenses in the space between the inner wall 120 and the outer wall 110 and thus contaminates the substrate heat treatment apparatus. Furthermore, the substrate heat treatment apparatus can be cooled by a gas introduced into the space between the inner wall 120 and the outer wall 110.

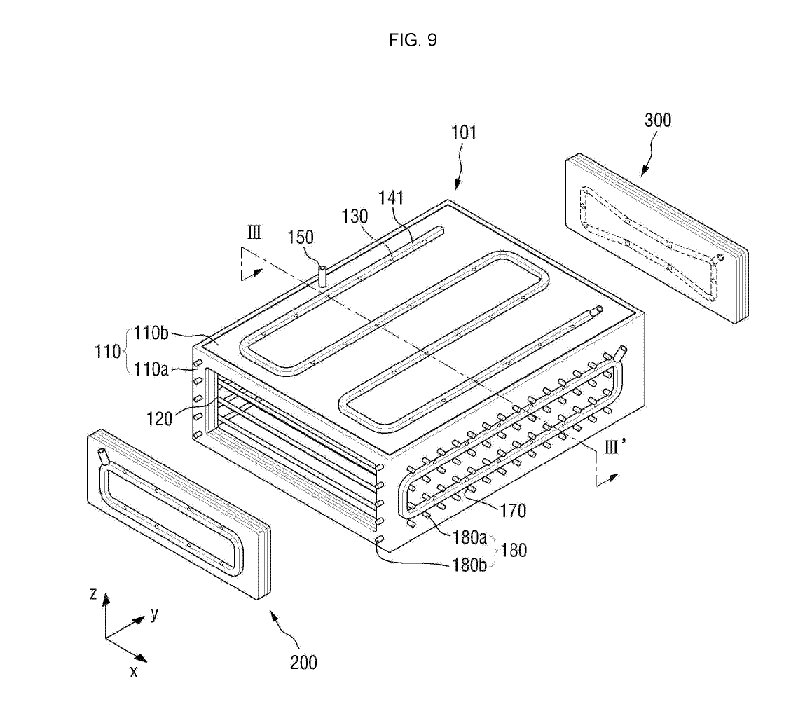

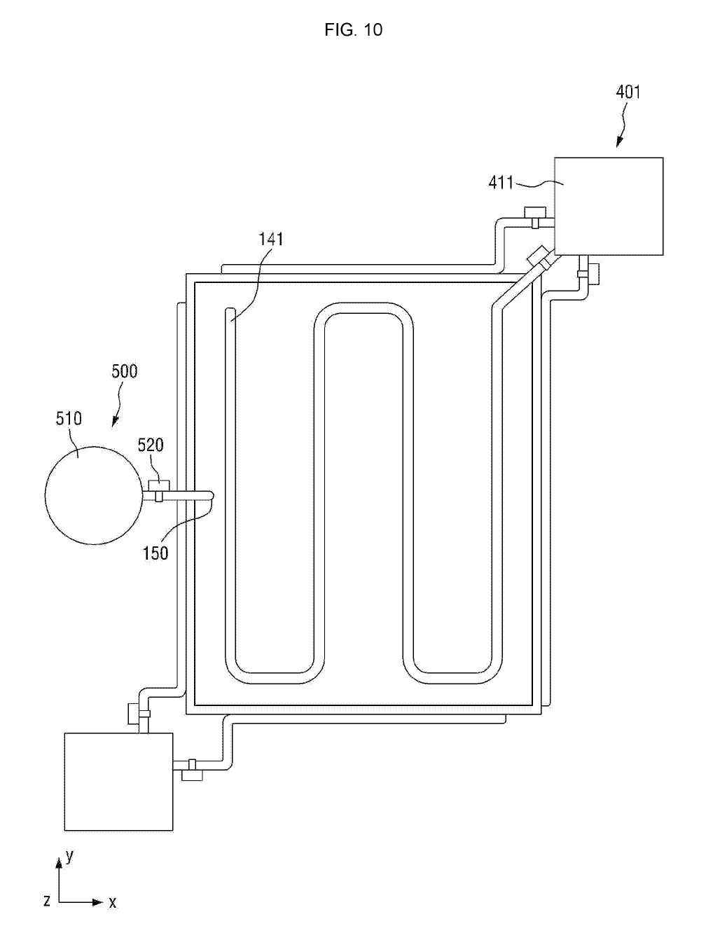

FIG. 9 is an exploded perspective view of a substrate heat treatment apparatus, according to another embodiment of the present invention. FIG. 10 is a plan view of the substrate heat treatment apparatus shown in FIG. 9, according to an example embodiment of the present invention. For simplicity, elements substantially identical to those of FIGS. 1 through 8 are indicated by like reference numerals, and a repetitive description thereof will not be provided.

Referring to FIG. 9, the number and shape of gas holes 130 formed in an outer wall 110 may be substantially identical (or identical) to those of the gas holes 130 shown in FIGS. 1 through 8. However, a gas pipe 141, which covers the gas holes 130, may be configured (or placed) in a different pattern from the gas pipe 140 shown in FIGS. 1 through 8. In an embodiment, a body 101 includes a plurality of gas pipes 141, and the gas pipes 141 are placed on different planes.

Referring to FIG. 10, two first gas suppliers 401 may be provided. In an embodiment, a first gas supplier 401 is placed adjacent to a first corner of the body 101, and the other first gas supplier 401 is placed adjacent to a second corner, which is opposite the first corner of the body 101. Each of the first gas suppliers 401 may include a first gas chamber 411, and the first gas chamber 411 may be connected to the gas pipes 141.

As described above, the substrate heat treatment apparatus, according to the current embodiment, can more easily adjust a first gas 810, which flows through each of the gas pipes 141, by using the two first gas suppliers 401.

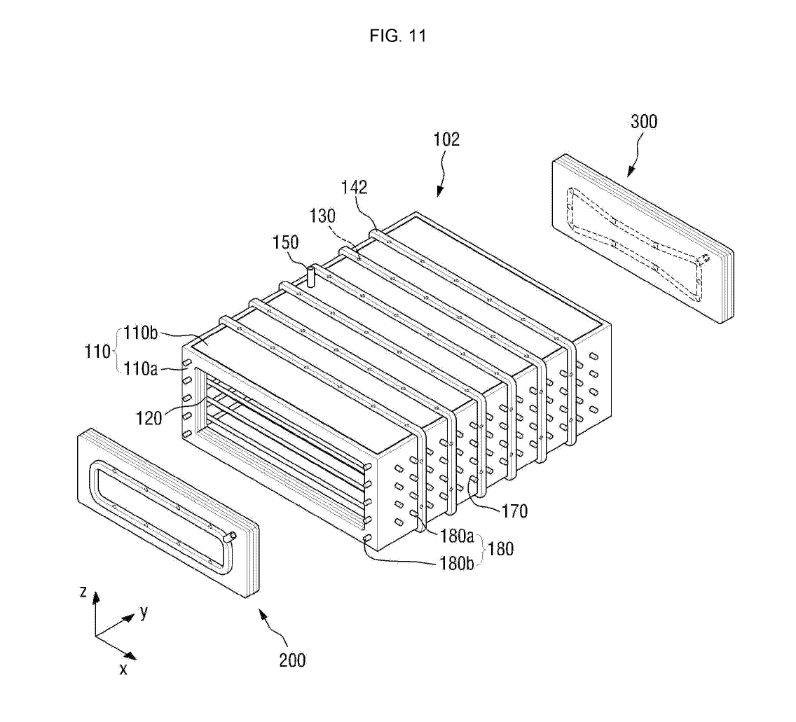

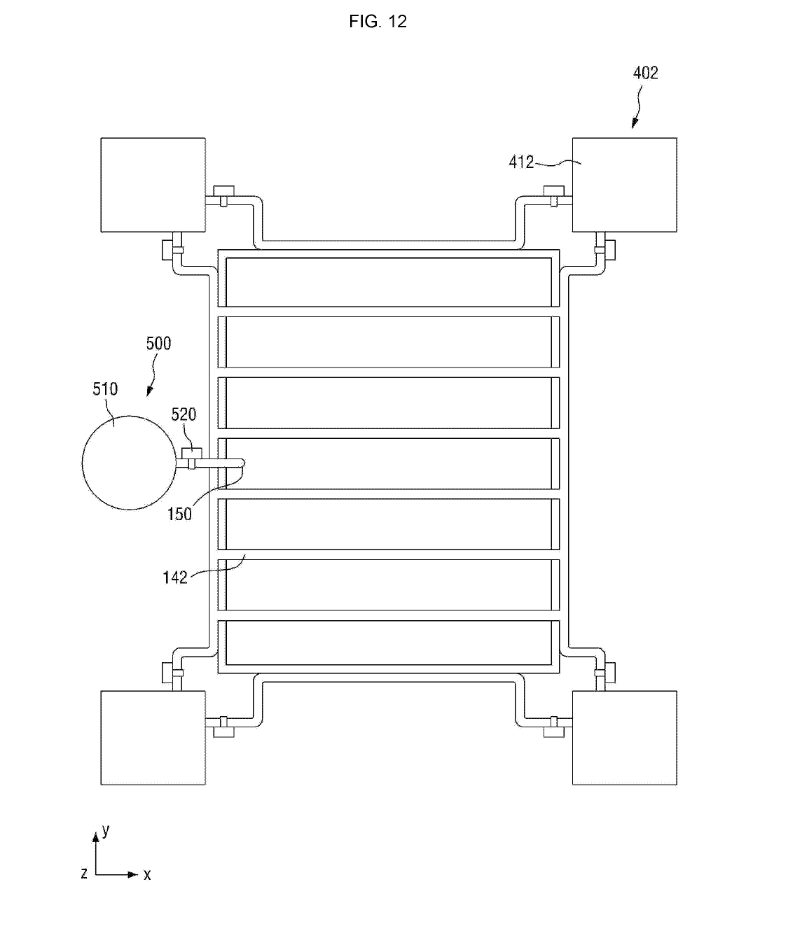

FIG. 11 is an exploded perspective view of a substrate heat treatment apparatus, according to another embodiment of the present invention. FIG. 12 is a plan view of the substrate heat treatment apparatus shown in FIG. 11, according to an example embodiment of the present invention. For simplicity, elements substantially identical to those of FIGS. 1 through 8 are indicated by like reference numerals, and a repetitive description thereof will not be provided.

Referring to FIG. 11, the number and shape of gas holes 130 formed in (or through) an outer wall 110 may be substantially identical (or identical) to those of the gas holes 130 shown in FIGS. 1 through 8. However, a gas pipe 142, which covers the gas holes 130, may be configured (or placed) in a different pattern from the gas pipe 140 shown in FIGS. 1 through 8. For example, the gas pipe 142 included in a body 102 may be wound around the body 102 in the form of a coil.

Referring to FIG. 12, four first gas suppliers 402 may be provided. In one embodiment, the four first gas suppliers 402 is placed adjacent to four corners of the body 102, respectively. Each of the first gas suppliers 402 may include a first gas chamber 412, and the first gas chamber 412 may be connected to the gas pipe 142.

As described above, the substrate heat treatment apparatus, according to the current embodiment, can more easily adjust a first gas 810, which flows through the gas pipe 142, by using the four first gas suppliers 402.

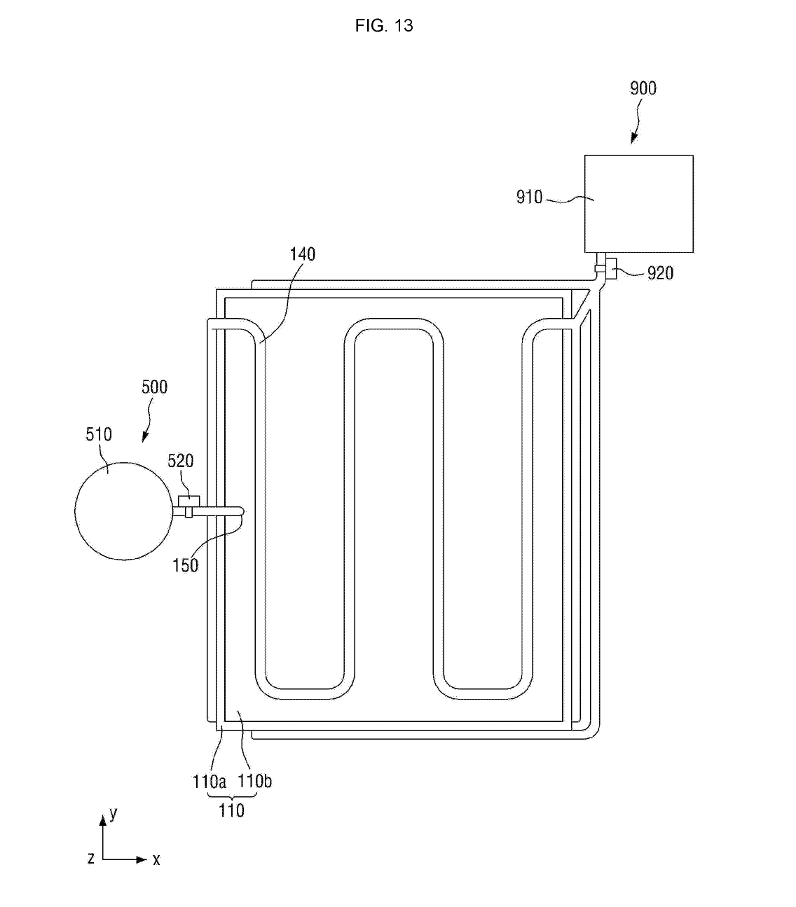

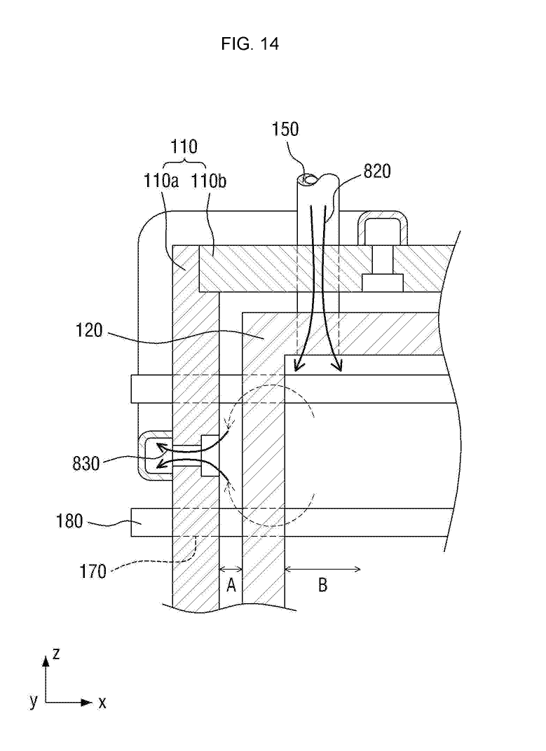

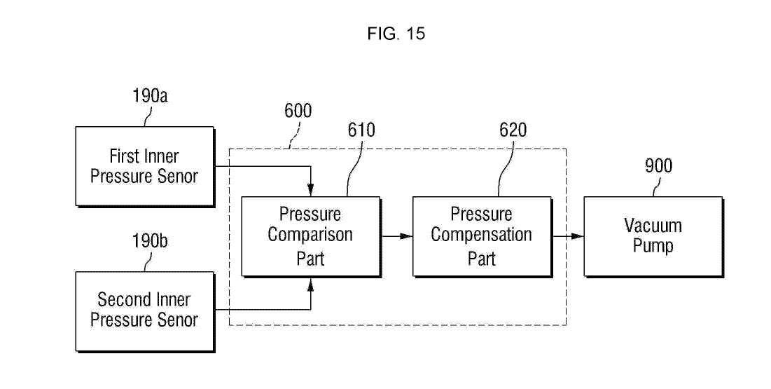

FIG. 13 is a plan view of a substrate heat treatment apparatus, according to another embodiment of the present invention. FIG. 14 is an enlarged cross-sectional view of a portion corresponding to the portion VI of FIG. 3 in the substrate heat treatment apparatus of the embodiment shown in FIG. 13. FIG. 15 is a block diagram of a pressure controller 600 included in the substrate heat treatment apparatus of the embodiment shown in FIG. 13. FIGS. 13 through 15 may pertain to the same or different embodiments. For simplicity, elements substantially identical to those of FIGS. 1 through 8 are indicated by like reference numerals, and a repetitive description thereof will not be provided.

Referring to FIG. 13, unlike in the substrate heat treatment apparatus of the embodiment of FIGS. 1 through 8, in the substrate heat treatment apparatus of the current embodiment, a vacuum pump 900 may be provided instead of a first gas supplier 400. The vacuum pump 900 is connected to a gas pipe 140 and gas holes 130 to suck out a gas inside an outer wall 110, that is, draw the gas out of the outer wall 110.

The vacuum pump 900 may include a vacuum chamber 910 and a vacuum gauge 920. The vacuum chamber 910 may store a sucked gas and discharge the stored gas to another place, and the vacuum gauge 920 may be installed on a connection portion between the vacuum chamber 910 and the gas pipe 140 to measure the degree of vacuum of the gas pipe 140.

In FIG. 14, the direction of arrows in the lower part of FIG. 6 is reversed. In one embodiment, not only a gas existing in a space between an inner wall (or inner shell) 120 and the outer wall (or outer shell) 110 but also a gas existing in a substrate housing space is sucked out through the gas holes 130. If a gas sucked out through the gas hole 130 is defined as a third gas 830, the third gas 830 may include a large amount of gas existing in the space between the inner wall 120 and the outer wall 110 and a small amount of gas existing in the substrate housing space. The gas existing in the substrate housing space may be a second gas 820 if no gas is generated from substrates during the heat treatment of the substrates.

As described above, because the gas existing in the space between the inner wall 120 and the outer wall 110 is discharged in larger amounts than the gas existing in the substrate housing space, the pressure in the space between the inner wall 120 and the outer wall 110 may be lower than the pressure in the substrate housing space.

Referring to FIG. 15, the pressure controller 600 may control the vacuum pump 900. For example, the pressure controller 600 may compare the pressure measured by a first inner pressure sensor 190a and the pressure measured by a second inner pressure sensor 190b and adjust the pressure in the space between the inner wall 120 and the outer wall 110 to be lower than the pressure in the substrate housing space. For example, the pressure controller 600 may adjust the driving force of the vacuum pump 900 such that a difference between the pressure in the space between the inner wall 120 and the outer wall 110 and the pressure in the substrate housing space is equal to or greater than a reference value (e.g., a preset value). In an example embodiment, when a difference value obtained by subtracting second pressure from first pressure is greater than a reference value (e.g., a preset value), a pressure compensation part 620 increases the amount of gas sucked per unit of time by increasing the driving force of the vacuum pump 900. When the difference value obtained by subtracting the second pressure from the first pressure is less than the reference value, the pressure compensation part 620 may reduce the amount of gas sucked per unit of time by reducing the driving force of the vacuum pump 900 or may not perform pressure compensation.

A substrate heat treatment method, according to an embodiment of the present invention, will now be described with reference to FIGS. 1 through 8.

The substrate heat treatment method, according to the current embodiment, includes feeding one or more substrates into a space surrounded by an inner wall (or inner shell) 120 and heating the substrates, and injecting a first gas 810 into a space between the inner wall 120 and an outer wall (or outer shell) 110, which surrounds the inner wall 120. The injecting of the first gas 810 may include adjusting the pressure in the space between the inner wall 120 and the outer wall 110 to be higher than the pressure in the space surrounded by the inner wall 120.

The substrate heat treatment method may further include injecting a second gas 820 into the space surrounded by the inner wall 120, after the feeding of the substrates into the space surrounded by the inner wall 120 and the heating of the substrates. If the second gas 820 is injected, the injecting of the first gas 810 may include selecting a first gas 810 corresponding to the second gas 820 and injecting the selected first gas 810.

A substrate heat treatment method, according to another embodiment of the present invention, will now be described with reference to FIGS. 13 through 15.

The substrate heat treatment method, according to the current embodiment, includes feeding one or more substrates into a space surrounded by an inner wall 120 and heating the substrates, and discharging a gas inside an outer wall 110 to the outside of the outer wall 110 through gas holes 130 formed in the outer wall 110, which surrounds the inner wall 120. The discharging of the gas inside the outer wall 110 to the outside of the outer wall 110 may include adjusting the pressure in a space between the inner wall 120 and the outer wall 110 to be lower than the pressure in the space surrounded by the inner wall 120.

Embodiments of the present invention provide at least one of the following enhancements.

For one, because the pressure in a space between an inner wall and an outer wall is higher than the pressure in a substrate housing space, a gas existing in the substrate housing space may not flow into the space between the inner wall and the outer wall. Therefore, it is possible to prevent generation of a foreign substance, which condenses in the space between the inner wall and the outer wall and thus contaminates a substrate heat treatment apparatus.

Furthermore, the substrate heat treatment apparatus can be cooled by a gas introduced into the space between the inner wall and the outer wall.

However, the embodiments of the present invention are not restricted to the one set forth herein. The above and other embodiments of the present invention will become more apparent to one of ordinary skill in the art to which the present invention pertains by referencing the claims.

While the present invention has been particularly shown and described with reference to example embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims, and equivalents thereof, rather than the foregoing description to indicate the scope of the invention.

What is claimed is:

1. A substrate heat treatment method comprising:
feeding one or more substrates into a space surrounded by an inner shell and heating the substrates; and
discharging a gas inside an outer shell configured to surround the inner shell to the outside of the outer shell,
wherein the discharging of the gas inside the outer shell to the outside of the outer shell comprises adjusting a pressure in the space between the inner shell and the outer shell to be lower than a pressure in the space surrounded by the inner shell.

2. The method of claim 1, wherein the heating the substrate is performed by at least one heater, and the discharging of the gas inside the outer shell to the outside of the outer shell is performed through at least one gas hole formed in the outer shell.

3. The method of claim 2, wherein the at least one heater comprises a plurality of heaters, and penetrates the inner shell and the outer shell.

4. The method of claim 2, wherein the at least one heater comprises a main heater configured to directly contact the substrate and an auxiliary heater configured to directly not contact the substrate.

5. The method of claim 2, wherein the at least one gas hole comprises a plurality of gas holes, the plurality of gas holes are coupled together by at least one gas pipe forming a passage through which the gas is discharged.

6. The method of claim 2, wherein the at least one gas hole becomes larger in size toward the inside of the outer shell.

7. The method of claim 2, adjusting the pressure in the space between the inner shell and the outer shell to be lower than a pressure in the space surrounded by the inner shell is performed by a first inner pressure sensor located in the space between the inner shell and the outer shell, a second inner pressure sensor located in the substrate housing space, and a pressure controller configured to compare a first pressure measured by the first inner pressure sensor with a second pressure measured by the second inner pressure sensor and to adjust the first pressure to be lower than the second pressure based on the comparison.

8. The method of claim 7, wherein the pressure controller is configured to control a difference between the first pressure and the second pressure to be equal to or greater than a reference value by adjusting a driving force of a vacuum pump coupled to the at least one gas hole.

9. The method of claim 2, further comprising supplying a reaction gas into the space surrounded by an inner shell,
wherein the discharging of the gas inside the outer shell to the outside of the outer shell comprises discharging the reaction gas and a gas generated from the substrate through the at least one gas hole.

10. The method of claim 1, wherein the inner shell comprises a heat insulator.

11. The method of claim 1, wherein the gas comprises at least one of air, nitrogen gas, helium gas, argon gas, and oxygen gas.
